(19) United States
(12) Patent Application Publication
(10) Pub. No.: US 2015/0316094 A1
(43) Pub. Date: Nov. 5, 2015

(54) BEARING, MORE PARTICULARLY ROLLING BEARING

(71) Applicant: Schaeffler Technologies AG & Co. KG, Herzogenaurach (DE)

(72) Inventor: Thomas Rink, Waldfenster (DE)

(73) Assignee: SCHAEFFLER TECHNOLOGIES AG & Co. KG, Herzogenaurach (DE)

(21) Appl. No.: 14/651,014

(22) PCT Filed: Nov. 7, 2013
(86) PCT No.: PCT/DE2013/200277

§ 371 Date: Jun. 10, 2015

(30) Foreign Application Priority Data
Dec. 10, 2012 (DE) 10 2012 222 631.1

(51) Int. Cl. F16C 19/52; G01R 33/06; F16C 41/00

(52) U.S. Cl. CPC F16C 19/522; F16C 41/007; G01R 33/06

(57) ABSTRACT

A bearing, more particularly to an antifriction bearing having a first bearing ring (1), a second bearing ring (2), and a claw pole arrangement (13), wherein the claw pole arrangement (3) includes a first claw ring (4) with a series of first claws (5) and a second claw ring (6), integrated in the circumferential direction of the axis of rotation, with a series of second claws, wherein the claw rings (4, 8) are arranged on the first bearing ring (1), and the claws of the two claw rings (4, 6) form magnetic circuits with a series of magnetic poles (8) surrounding the axis of rotation, and wherein the magnetic poles (8) are arranged on the second bearing (3). The objective of specifying a bearing, more particularly an anti-friction bearing, having a detection device for bearing forces which is structurally easy to integrate, is met according to the invention by a gap (10) being formed in the circumferential direction at least in some sections between the first claw ring (4) and the second claw ring (6), wherein beyond the gap (10), the magnetic circuit is closed between a claw (5) of the first claw ring (4) and a claw of the second claw ring (6) adjacent in a circumferential direction, and by a magnetic sensor (11) arranged in the region of the gap (10) to detect the magnetic field passing through the gap (10).

### FIELD OF THE INVENTION

The invention relates to a bearing, and more particularly, to an anti-friction bearing.

Various forces, in particular, those that act in the radial direction with respect to the rotational axis of the bearing and cause a change of the spacing between the two bearing rings, act on bearings, in particular, on anti-friction bearings. The qualitative or even quantitative detection of such bearing forces or the change of the, in particular, radial spacing of the two bearing rings relative to each other is complicated, but important for the design and monitoring of the bearing.

For example, it is known to attach strain gauges to the end face or lateral surface of one of the bearing rings that supply an electrical signal when the strain gauges are stressed due to the application of forces. Such strain gauges can be attached only in a complicated and hard-to-reproduce manner; furthermore, an additional power supply is required.

From the prior art, bearings are known, in particular, anti-friction bearings, which comprise a claw pole generator for generating electrical energy from the relative rotational movement of the two bearing rings. In particular, bearings are known, especially anti-friction bearings, comprising a first bearing ring, a second bearing ring, and a claw pole arrangement, wherein the claw pole arrangement comprises a first claw ring with a series of first claws and a second claw ring offset in the circumferential direction of the rotational axis with a series of second claws, wherein the claws of the two claw rings form magnetic circuits with a series of magnetic poles surrounding the rotational axis. Here, the two claw rings are arranged on the first bearing ring and the series of magnetic poles are attached to the second bearing ring. The claw pole arrangement described above is completed by an induction coil between the two claw rings and surrounds the rotational axis such that for a relative rotation of the first bearing ring and the second bearing ring, the induction coil is surrounded by magnetic circuits, whose orientation changes as a function of the rotational speed of the bearing, so that an alternating electrical current is induced in the induction coil that can be tapped as useful energy and whose frequency is dependent on the rotational speed of the bearing, so that a claw pole generator can also be provided indirectly as a rotational speed sensor. The complete closure of the magnetic circuit surrounding the induction coil, which is essential for the functioning of the claw pole generator, is created on the sides of the magnetic poles to the second bearing ring either by a magnetic flux ring that connects opposite magnetic poles adjacent in the circumferential direction in a magnetically conductive manner or by the magnetically conductive body of the second bearing ring. The complete closure of the magnetic circuit surrounding the induction coil, which is essential for the functioning of the claw pole generator, is created on the sides of the claw sheets on the first bearing ring by a flux element (DE 10 2011 075 548 A1) connecting the two claw sheets in a direct magnetically conductive manner or by the magnetically conductive body of the first bearing ring (DE 10 2010 018 472 A1). Changes to the spacing between the two bearing rings that make a change of the magnetic flux between the magnetic poles on the second bearing ring detectable to the claws on the first bearing ring can be detected without additional elements in the claw pole arrangements expanded into a claw pole generator, because the induction voltage in the induction coil is distributed over the entire circumference.

### SUMMARY

The objective of the invention is to provide a bearing, more particularly, an anti-friction bearing, with a detection device for bearing forces that can be integrated in a structurally simple way.

This objective is achieved according to the invention in that, in the circumferential direction, at least in some sections, a gap is formed between the first claw ring and the second claw ring, wherein the magnetic circuit is closed over the gap between a claw of the first claw ring and a claw of the second claw ring adjacent in the circumferential direction, and that, in the area of the gap, a magnetic sensor is arranged that detects the magnetic field going through the gap.

The magnetic flux going through the gap formed at least in some sections in the circumferential direction is dependent on the spacing of the claw of the first claw ring to the magnetic pole opposite this claw and on the spacing of the claw of the second claw ring adjacent to this claw in the circumferential direction to the oppositely poled magnetic pole opposite this adjacent claw, consequently, on the spacing of the two bearing rings, so that the magnetic field detected by the magnetic sensor in the defined gap between the two claw rings is dependent on the spacing of the two bearing rings to each other and thus indirectly on the forces acting on the bearing in the circumferential area of the gap.

The gap can extend in the circumferential direction of the bearing only by the amount over which the magnetic flux runs through the two drawn claws of the claw pair adjacent in the circumferential direction, wherein it is understood that several such claw pairs can be provided with spacing in the circumferential direction. The gap, however, can also extend along the entire circumference of the bearing.

The gap width, that is, the smallest distance between the two claw sheets, is designed so that a magnetic flux through a physical, magnetically conductive part between the two claw sheets is prevented, but also so that the magnetic circuit can be closed over the gap, because the magnetic flux density emerges from one of the claw sheets close to its surface in the direction toward the other claw sheet and in this way passes through the gap.

Advantageously it is provided that the gap is formed as an air gap, wherein, in the air gap, a magnetic sensor can be arranged in an especially simple and easily accessible manner.

Advantageously it is provided that the gap is filled with a magnetically non-conductive material, in particular, with a plastic. The magnetic sensor can here be arranged on or in the magnetically non-conductive filler material.

Advantageously it is provided that an insulation ring made from a magnetically non-conductive material, in particular, from a plastic, is arranged between the claw rings and the first bearing ring. The insulation ring suppresses stray magnetic flux lines that do not run through the gap with the magnetic sensor.

With respect to the insulation ring, it is advantageously provided, in particular, that the claw rings are held on recesses of the insulation ring and that the insulation ring fills up the gap between the claw rings at least in some sections. The insulation ring thus fulfills the additional function of holding the two claw rings and here provides at least partially the magnetically non-conductive material that fills up the gap between the two claw rings.

Advantageously it is provided that the magnetic sensor is arranged on or in the insulation ring. The insulation ring thus fulfills the additional function of holding the magnetic sensor and holding, in particular, its electrical lines at least in some sections.

Advantageously it is provided that the two claw rings surround an induction coil surrounding the rotational axis, wherein the magnetic circuits surround the induction coil. The electrical voltage induced in the induction coil can here be provided as an energy supply for the at least one magnetic sensor in the at least one gap. The influence of the magnetic field detected by the magnetic sensor in the gap by the frequency-dependent alternating magnetic field surrounding the induction coil can be overcome, for example, by electronic post-processing of the signal of the magnetic sensor, especially by load balancing of the alternating voltage signal of the induction coil.

As an alternative here, it is advantageously provided that the magnetic sensor is loaded by an external voltage source.

As an alternative here, it can be provided, in turn, that the magnetic sensor is loaded by an energy storage device that is charged by the induction coil.

The magnetic sensor detecting the magnetic field in the gap can be formed, for example, as a Hall sensor or as an XMR sensor.

Additional advantages and features of the invention result from the dependent claims and from the description of an embodiment.

The invention will be described and explained below in more detail with reference to the accompanying drawings.

### BRIEF DESCRIPTION OF THE DRAWINGS

FIG. 1 shows a plan view of an embodiment of a bearing according to the invention,

FIG. 2 shows, in sections, a partially sectioned view of the embodiment shown in FIG. 1 along the section line A-A from FIG. 1, and

FIG. 3 shows, in sections, a partially sectioned view of the embodiment shown in FIG. 1 and FIG. 2 along the section line B-B from FIG. 1.

### DETAILED DESCRIPTION OF THE PREFERRED EMBODIMENTS

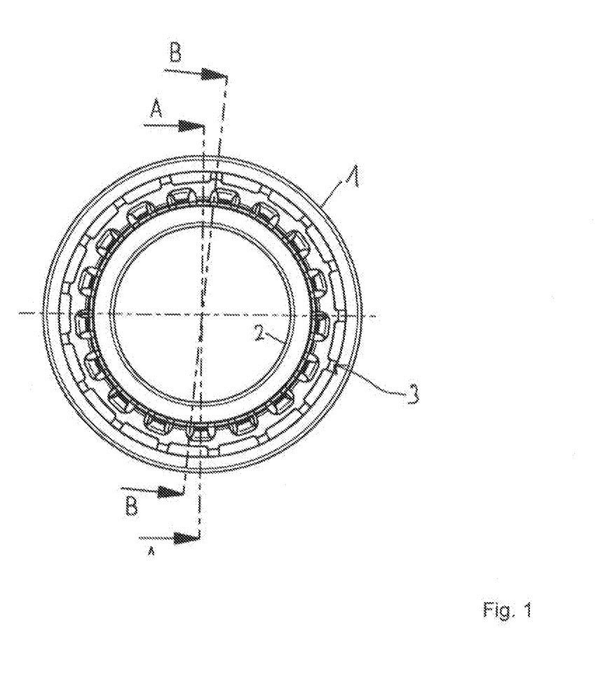

FIG. 1 shows a plan view of a bearing formed as a one-row ball bearing, in particular, as an anti-friction bearing, comprising a first, outer bearing ring 1, a second, inner bearing ring 2, and a claw pole arrangement 3 that is arranged between the bearing rings 1, 2 and is arranged between the two bearing rings 1, 2.

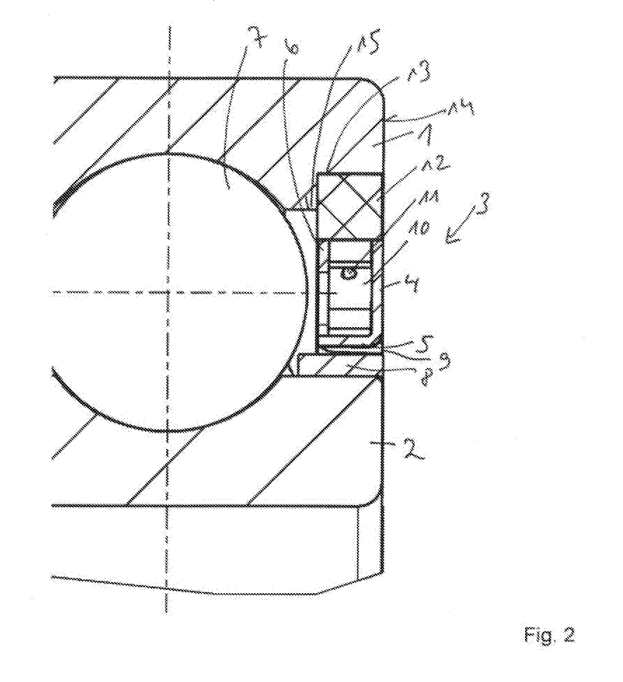

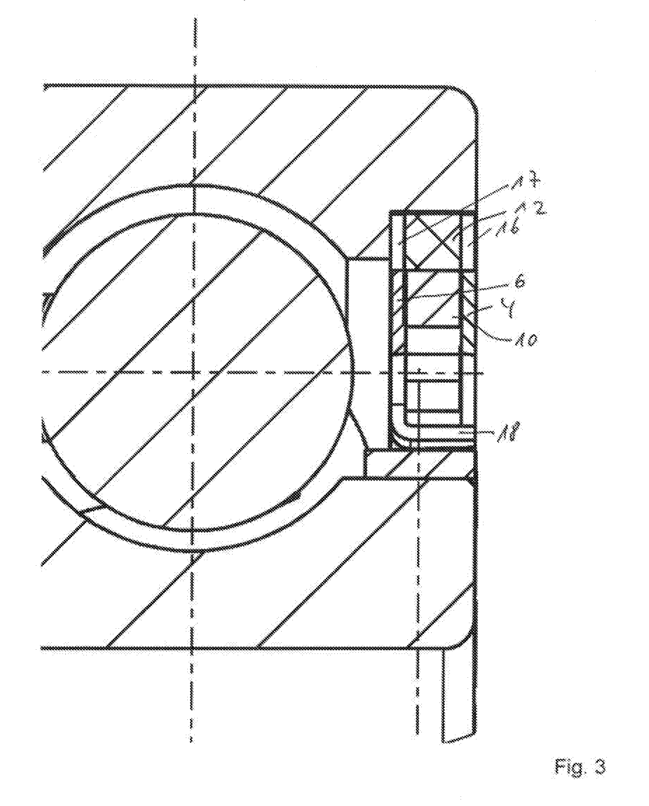

FIG. 2 shows the claw pole arrangement 3 in a first section view, wherein the claw pole arrangement 3 comprises a first claw ring 4 with a series of first claws whose sole visible claw is marked with the reference symbol ‘5’ and a second claw ring 6 offset in the circumferential direction of the rotational axis of the bearing with a series of second claws, wherein the claws of the second claw ring 6 are arranged above or below the plane of the paper. Here, the two claw rings 4, 6 are arranged rotationally locked on the first bearing ring 1. The two claw rings 4, 6 are each formed as flat ring disks that extend radially with respect to the rotational axis of the bearing, wherein claws are each formed as sections of the claw rings 4, 6 extending axially, that is, parallel to the rotational axis of the bearing. The first claw 5 of the first claw ring 4 is here set off in the direction toward the bearing interior, pointing toward a roller body 7. The claws of the second claw ring 6 not shown in FIG. 2 are also set off axially, but pointing away from the roller body 7. The claw of the other, second claw ring 6 adjacent to the claw 5 of the first claw ring 4 in the circumferential direction is shown in FIG. 3 in a side view and is provided there with the reference symbol ‘18’.

On the second bearing ring 2 there is a series of magnetic poles surrounding the rotational axis of the bearing, wherein the shown first magnetic pole 8 is opposite the claw 5 of the first claw ring 4 while maintaining a bearing gap 9 and a second pole oppositely poled relative to the first magnetic pole 8 is opposite, under the plane of the paper, the claw of the second claw ring 6 also located there.

Between the two claw rings 4, 6 on their edges pointing toward the first bearing ring 1 there is a gap 10 that extends in some sections, in the area of the claw 5 of the first claw ring 4 and the claw of the second claw ring 6 interacting with the claw 5 in the circumferential direction of the bearing.

It is provided that a magnetic circuit is formed starting from the magnetic pole 8 (for example, a north pole) via the claw 5, the first claw ring 4, through the gap 10 to the second claw ring 6 and the other claw of the second claw ring 6 adjacent to the claw 5 in the circumferential direction and located below the plane of the paper to the magnetic pole (in this case, a south pole) adjacent in the circumferential direction and oppositely poled to the magnetic pole 8 and also located below the plane of the paper.

The gap 10 is dimensioned in its axial spacing of the two flat claw rings 4, 6 so that the magnetic circuit is closed over the gap 10 between a claw 5 of the first claw ring 4 and a claw of the second claw ring 6 adjacent in the circumferential direction. The gap 10 is formed by the defined elimination of a physical, magnetically conductive connection between the two claw rings 4, 6.

In the area of the gap 10 there is a magnetic sensor 11 that detects the magnetic field passing through the gap 10, wherein the magnetic sensor 11 is formed, for example, as a Hall sensor.

The magnetic field detected by the magnetic sensor 11 in the area of the gap 10 between the two claw rings 4, 6 depends essentially on the amount of radial extent of the bearing gap 9, that is, on the spacing of the claw 5 to the magnetic pole 8 and on the spacing of the claw 18 adjacent to the claw 5 in the circumferential direction (FIG. 3) of the other, second claw ring 6 to the magnetic pole oppositely poled to the pole 8 and adjacent to the magnetic pole 8 in the circumferential direction and is thus a measure for the width of the bearing gap 9 in the radial direction with respect to the rotational axis of the bearing, and thus indirectly for the bearing forces that act in the radial direction and influence the radial spacing of the bearing rings 1, 2.

For the gap 10 between the two claw sheets 4, 6 it is provided that the gap 10 is formed as an air gap at least in some sections on the radially inner side pointing toward the claws 5, so that the claw sheets 4, 6 are separated close to the claws 5 by air as a magnetically non-conductive material.

For a section of the gap 10 pointing from the claws 5 toward the first bearing ring 1 it is provided that the gap 10 is filled in this section with a magnetically non-conductive material, namely a magnetically non-conductive plastic.

Between the two claw rings 4, 6 and the first bearing ring 1 there is, namely, an insulation ring 12 made from a magnetically non-conductive material, namely made from plastic, wherein the insulation ring 12 projects into the gap 10 in some sections and fills up the gap 10 there with the magnetically non-conductive plastic.

The insulation ring 12 holds the two edges of the claw rings 4, 6 pointing toward the first bearing ring 1 at a distance from the magnetically conductive material of the first bearing ring 1 and ensures that no parasitic magnetic flux lines that bypass the magnetic sensor 11 emerge over the first bearing ring 1.

The insulation ring 12 is held in a receptacle groove 13 on an end face 14 of the first bearing ring 1, flush with the bordering end face 14, and projects radially over the inner lateral surface 15 of the first bearing ring 1 pointing toward the second bearing ring 2 so far that contact between the two claw rings 4, 6 with the material of the first bearing ring 1 is prevented.

The claw rings 4, 6 are held at the edge on recesses 16, 17 (FIG. 3) of the insulation ring 12, wherein it is further provided that the insulation ring 12 fills up the gap 10 between the claw rings 4, 6 in some sections. The recesses 16, 17 are formed as flat, open grooves in the material of the insulation ring 12 in which the flat edge sections of the claw rings 4, 6 are held flush with the bordering surface of the insulation ring 12.

It is further provided that the magnetic sensor 11 is arranged on an edge of the insulation ring 12 pointing toward the second bearing ring 2 between the two claw rings 4, 6 in the gap 10, wherein, in the insulation ring 12 there are electrical lines for supplying the magnetic sensor 11.

Up to the insulation ring 12 reaching in some section into the gap 10 between the claw rings 4, 6, the area between the claw rings 4, 6 is formed free from a filling material and in particular, as an air gap; in one modification of the shown embodiment, an induction coil could also be placed between the claw rings 4, 6 with a magnetically non-conductive coil material, such as copper.

### LIST OF REFERENCE NUMBERS

1 First bearing ring

2 Second bearing ring

3 Claw pole arrangement

4 First claw ring

5 Claw of the first claw ring 4

6 Second claw ring

7 Roller body

8 Magnetic pole

9 Bearing gap

10 Gap

11 Magnetic sensor

12 Insulation ring

13 Receptacle groove

14 End face of the first bearing ring 1

15 Inner lateral surface of the first bearing ring 1

16 Recess

17 Recess

18 Claw of the second claw ring 6

1. A bearing, comprising:
a first bearing ring,
a second bearing ring, and
a claw pole arrangement,
the claw pole arrangement comprises a first claw ring with a series of first claws and a second claw ring with a series of second claws offset in a circumferential direction of a rotational axis,
the claw rings are arranged on the first bearing ring,
the claws of the first and second claw rings form magnetic circuits with a series of magnetic poles surrounding the rotational axis that are arranged on the second bearing ring,
in the circumferential direction, at least in some sections a gap is formed between the first claw ring and the second claw ring, wherein the magnetic circuit is closed over the gap between one of the claws of the first claw ring and one of the claws of the second claw ring adjacent in the circumferential direction, and
a magnetic sensor that detects a magnetic field passing through the gap is arranged in an area of the gap.

2. The bearing according to claim 1, wherein the gap is constructed as an air gap.

3. The bearing according to claim 1, wherein the gap is filled with a magnetically non-conductive material.

4. The bearing according to claim 1, wherein an insulation ring made from a magnetically non-conductive material is arranged between the claw rings and the first bearing ring.

5. The bearing according to claim 4, wherein the claw rings are held in recesses of the insulation ring and the insulation ring fills the gap between the claw rings at least in some sections.

6. The bearing according to claim 4, wherein the magnetic sensor is arranged on or in the insulation ring.

7. The bearing according to claim 1, wherein the two claw rings surround an induction coil surrounding the rotational axis, and the magnetic circuits surround the induction coil.

8. The bearing according to claim 7, wherein the magnetic sensor is loaded by an energy storage device that is charged by the induction coil.

9. The bearing according to claim 3, wherein the magnetically non-conductive material is plastic.

10. The bearing according to claim 4, wherein the insulation ring is made from plastic.
